(19) United States
(12) Patent Application Publication
(10) Pub. No.: US 2024/0224666 A1
(43) Pub. Date: Jul. 4, 2024

(54) Display Device and Method for Manufacturing the Same

(71) Applicant: LG Display Co., Ltd., Seoul (KR)

(72) Inventor: Joonyoung Heo, Seoul (KR)

(21) Appl. No.: 18/531,300

(22) Filed: Dec. 6, 2023

(30) Foreign Application Priority Data
Dec. 23, 2022 (KR) 10-2022-0183588

(51) Int. Cl. H10K 59/131; H10K 59/122

(52) U.S. Cl. CPC H10K 59/131; H10K 59/122

(57) ABSTRACT

Disclosed is a display device in which a power connection line contacts a cathode contact disposed on a structure disposed in each sub-pixel and thus is electrically connected to a cathode electrode layer, such that power is stably supplied to each of a plurality of sub-pixels via the power connection line electrically connected to a power line.

### CROSS-REFERENCE TO RELATED APPLICATION

This application claims priority from Republic of Korea Patent Application No. 10-2022-0183588 filed on Dec. 23, 2022 in the Korean Intellectual Property Office, and all the benefits accruing therefrom under 35 U.S.C. 119, which is hereby incorporated by reference in its entirety.

### BACKGROUND

### Field

The present disclosure relates to a display device and a method for manufacturing the same. More particularly, the present disclosure relates to a display device having a structure for applying power to a cathode electrode layer and a method for manufacturing the same.

### Description of Related Art

A display device is implemented in very diverse forms such as televisions, monitors, smart phones, tablet personal computers PCs, laptops, and wearable devices.

An organic light-emitting display device (OLED) as an example of the display device is a self-luminous display device, and is not only advantageous in terms of power consumption due to low operation voltage thereof, but also has excellent advantages in color rendering, response speed, viewing angle, and contrast ratio.

The organic light-emitting display device may include a plurality of pixels at pixel areas defined by gate lines and data lines intersecting each other.

In this case, power may be applied to each of the plurality of pixels to drive each of the plurality of pixels.

### SUMMARY

The display device may include a power supply for applying power to a plurality of pixels and a power line for supplying power from the power supply thereto.

The power line may be a high-potential voltage (VDD) line or a low-potential voltage (VSS) line.

For example, when the display device is embodied as an organic light-emitting display device, the low-potential voltage line may apply a low-potential voltage to a cathode electrode constituting the organic light-emitting diode.

Applying the low-potential voltage to the cathode electrode may allow each pixel including the organic light-emitting diode connected to the cathode electrode to emit light.

In order for the plurality of pixels disposed in a display area to emit light, the low-potential voltage should be applied to the cathode electrode connected to the plurality of pixels.

For this reason, the cathode electrode may be formed throughout the display area.

For example, the cathode electrode may be formed in a form of a surface electrode covering an entire surface of the display area and may be formed as a common electrode to the plurality of pixels.

However, when the cathode electrode is formed in the form of the surface electrode covering the entire surface of the display area, a parasitic capacitor may be generated between the cathode electrode and a data line disposed to overlap each other.

When the parasitic capacitor is generated between the cathode electrode and the data line, decrease in an electrical transmission rate (RC (resistive-capacitive) delay) occurs. Thus, a high-speed operation of the display device may not be achieved.

Accordingly, the inventors of the present disclosure conducted several experiments in order to reduce the decrease in the electrical transmission rate of the display device.

Based on the several experiments, the inventors of the present disclosure have invented a display device having a structure capable of supplying stable power to the cathode electrode layer while reducing the generation of the parasitic capacitor between the cathode electrode layer and the data line, and a method for manufacturing the display device.

A technical purpose according to an embodiment of the present disclosure is to provide a display device having a structure capable of stably supplying power to a plurality of sub-pixels and a method for manufacturing the display device.

Moreover, a technical purpose according to an embodiment of the present disclosure is to provide a display device capable of improving light extraction efficiency in an organic light-emissive layer included in each of a plurality of sub-pixels and a method for manufacturing the display device.

Moreover, a technical purpose according to an embodiment of the present disclosure is to provide a display device capable of reducing generation of lateral leakage current in an organic light-emissive layer included in each of a plurality of sub-pixels, and a method for manufacturing the display device.

Moreover, a technical purpose according to an embodiment of the present disclosure is to provide a display device that may reduce the generation of the parasitic capacitor between the cathode electrode layer and the data line, and a method for manufacturing the display device.

Moreover, a technical purpose according to an embodiment of the present disclosure is to provide a display device that may reduce the generation of the parasitic capacitor between a power connection line and the data line, and a method for manufacturing the display device.

Moreover, a technical purpose according to an embodiment of the present disclosure is to provide a display device capable of reducing damage to the organic light-emissive layer that may occur during a formation process of the organic light-emissive layer included in each of a plurality of sub-pixels, and a method for manufacturing the display device.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a display device comprises: a plurality of sub-pixels; a power line configured to supply a voltage; a plurality of structures, each structure respectively disposed in a corresponding one of the plurality of sub-pixels; and a power connection line overlapping the plurality of structures, the power connection line electrically connected to the plurality of sub-pixels and the power line, and supplies the voltage from the power line to the plurality of sub-pixels, wherein each of the plurality of sub-pixels includes an organic light-emissive layer, a cathode electrode layer on the organic light-emissive layer, and a passivation layer on the cathode electrode layer, the passivation layer including an opening that exposes a portion of the cathode electrode layer that is on a corresponding structure from the plurality of structures such that the portion of the cathode electrode layer is in contact with the power connection line, wherein organic light-emissive layers of adjacent sub-pixels from the plurality of sub-pixels are disconnected from each other, cathode electrode layers of the adjacent sub-pixels are disconnected from each other, and passivation layers of the adjacent sub-pixels are disconnected from each other.

In one embodiment, a display device comprises: a substrate; a plurality of sub-pixels on the substrate; a bank layer on the substrate; a structure on the bank layer; an organic light-emissive layer, a cathode electrode layer on the organic light-emissive layer, and a passivation layer on the cathode electrode layer in a sub-pixel from the plurality of sub-pixels such that a portion of the organic light-emissive layer, a portion of the cathode electrode layer, and a portion of the passivation layer overlap the bank layer and the structure, the passivation layer including an opening that exposes a portion of the cathode electrode layer that is on the structure; and a power connection line overlapping the structure such that the structure is between the power connection line and the substrate, wherein the portion of the cathode electrode layer is in contact with the power connection line.

In one embodiment, a method for manufacturing a display device comprises: forming a plurality of data lines on a substrate; forming a plurality of anode electrode layers, each anode electrode layer formed in a corresponding sub-pixel from a plurality of sub-pixels; forming a bank layer on the plurality of anode electrode layers, the bank layer including a plurality of openings each exposing a portion of a corresponding anode electrode layer from the plurality of anode electrode layers; forming a plurality of structures on the bank layer, each structure formed in a corresponding sub-pixel from the plurality of sub-pixels; forming a first protective layer and a first photoresist film on the bank layer and exposing a first opening from the plurality of openings that corresponds to a first sub-pixel from the plurality of sub-pixels; sequentially forming a first organic light-emissive layer configured to emit light of a first color in the first opening, a first cathode electrode layer on the first organic light-emissive layer, and a first passivation layer on the first cathode electrode layer, and removing the first protective layer and the first photoresist film; forming a second protective layer and a second photoresist film on the bank layer and exposing a second opening from the plurality of openings that corresponds to a second sub-pixel from the plurality of sub-pixels; sequentially forming a second organic light-emissive layer configured to emit light of a second color in the second opening, a second cathode electrode layer on the second organic light-emissive layer, and a second passivation layer on the second cathode electrode layer, and removing the second protective layer and the second photoresist film; forming a third protective layer and a third photoresist film on the bank layer and exposing a third opening from the plurality of openings that corresponds to a third sub-pixel from the plurality of sub-pixels; sequentially forming a third organic light-emissive layer configured to emit light of a third color in the third opening, a third cathode electrode layer on the third organic light-emissive layer, and a third passivation layer on the third cathode electrode layer, and removing the third protective layer and the third photoresist film; forming a first capping layer that covers the first passivation layer, the second passivation layer, and the third passivation layer; etching a partial area of each of the first capping layer, the first passivation layer, the second passivation layer, and the third passivation layer such that a partial area of each of the first cathode electrode layer, the second cathode electrode layer, and the third cathode electrode layer overlapping the structure are exposed; and forming a power connection line on the first capping layer, the power connection line connected to the exposed partial area of the first cathode electrode layer, the exposed partial area of the second cathode electrode layer, and the exposed partial area of the third cathode electrode layer.

In one embodiment, a display device comprises: a substrate; a bank on the substrate, the bank including an opening; a structure on the bank that is non-overlapping with the opening; a power connection line including a portion that overlaps the structure, the power connection line configured to supply a voltage; an anode electrode layer in the opening; an organic light-emissive layer including a first portion and a second portion, the first portion of the organic light-emissive layer on the anode electrode layer in the opening and the second portion of the organic light-emissive layer on the structure; a cathode electrode layer including a first portion and a second portion, the first portion of the cathode electrode layer on the first portion of the organic light-emissive layer in the opening and the second portion of the cathode electrode layer on the second portion of the organic light-emissive layer and the structure, the second portion of the cathode electrode layer in contact with the portion of the power connection line that overlaps the structure and receives the voltage from the power connection line; and a passivation layer including a first portion and a second portion, the first portion of the passivation layer on the first portion of the cathode electrode layer in the opening and the second portion of the passivation layer on the second portion of the organic light-emissive layer and the structure without being between the second portion of the cathode electrode layer and the portion of the power connection line that is in contact with the second portion of the cathode electrode layer.

According to the embodiment of the present disclosure, the cathode electrode layer and the power connection line are electrically connected to each other at the cathode contact provided on the structure of each sub-pixel. Thus, the power may be stably supplied to each of the plurality of sub-pixels via the power connection line electrically connected to the power line.

Moreover, according to the embodiment of the present disclosure, the adjacent organic light-emissive layers, the adjacent cathode electrode layers, and the adjacent passivation layers of adjacent sub-pixels are disconnected from each other, respectively. Thus, the light extraction efficiency from the organic light-emissive layer may be improved due to the occurrence of an out-coupling phenomenon that allows the light from the organic light-emissive layer to escape from the disconnected end to the outside. Thus, a low-power display device may be implemented.

Moreover, according to the embodiment of the present disclosure, the adjacent organic light-emissive layers, the adjacent cathode electrode layers, and the adjacent passivation layers of adjacent sub-pixels are disconnected from each other, respectively. Thus, the occurrence of lateral leakage current in the organic light-emissive layer that may occur when the adjacent organic light-emissive layers are integral with each other and extend continuously, and are connected to each other may be reduced.

Moreover, according to the embodiment of the present disclosure, the cathode electrode layer and the data line are disposed so as not to overlap each other in the vertical direction, thereby reducing the generation of the parasitic capacitor between the cathode electrode layer and the data line. Thus, the occurrence of the decrease in the electrical transmission rate (the RC delay) may be reduced.

Moreover, according to the embodiment of the present disclosure, the bank layer and the capping layer are disposed between the power connection line and the data line to increase a distance between the power connection line and the data line, thereby reducing the generation of the parasitic capacitor between the power connection line and the data line, and thus reducing the occurrence of the decrease in the electrical transmission rate (the RC delay).

Moreover, according to the embodiment of the present disclosure, the organic light-emissive layer rendering the first color, the cathode electrode layer, and the passivation layer may be formed, and subsequently, the organic light rendering the second color may be additionally formed using the same process as that on the organic light-emissive layer rendering the first color and subsequently, the organic light rendering the third color may be additionally formed using the same process as that on the organic light-emissive layer rendering the first color. Therefore, the passivation layer disposed on the organic light-emissive layer may act as a protective film that reduces deterioration of the organic light-emissive layer that may occur in a continuous process for forming the organic light-emissive layers corresponding to the sub-pixels. Thus, the damage to the organic light-emissive layer may be reduced.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF DRAWINGS

FIG. 1A and FIG. 1B are schematic plan views of display devices according to embodiments of the present disclosure, respectively.

FIG. 2 is a circuit diagram of one sub-pixel of a display device according to an embodiment of the present disclosure.

FIG. 3A is an enlarged plan view of a plurality of sub-pixels of a display device as shown in FIG. 1A according to an embodiment of the present disclosure.

FIG. 3B is an enlarged plan view of a plurality of sub-pixels of a display device as shown in FIG. 1A according to another embodiment of the present disclosure.

FIG. 3C is an enlarged plan view of a plurality of sub-pixels of a display device as shown in FIG. 1B according to still another embodiment of the present disclosure.

FIG. 4 is a cross-sectional view of a plurality of sub-pixels of a display device as shown in FIG. 3A and FIG. 3B according to an embodiment of the present disclosure.

FIG. 5 is a cross-sectional view of a plurality of sub-pixels of a display device as shown in FIG. 3C according to another embodiment of the present disclosure.

FIG. 6A to FIG. 6K are plan views of a plurality of sub-pixels in a process of manufacturing a display device according to an embodiment of the present disclosure.

FIG. 7A to FIG. 7K are cross-sectional views respectively corresponding to FIG. 6A to FIG. 6K according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

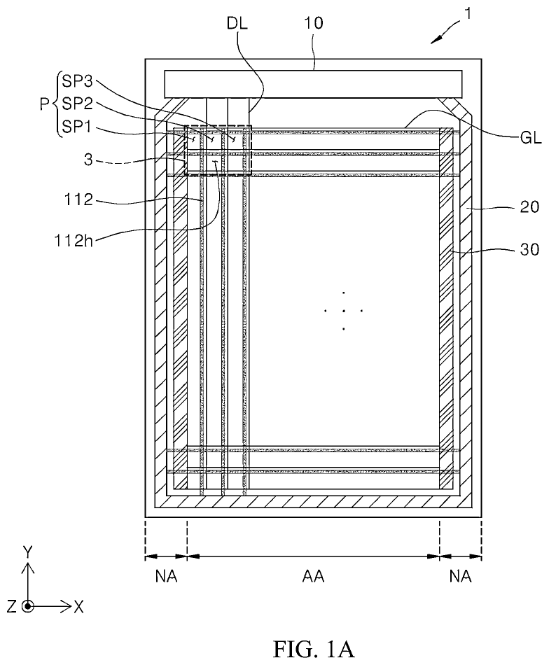

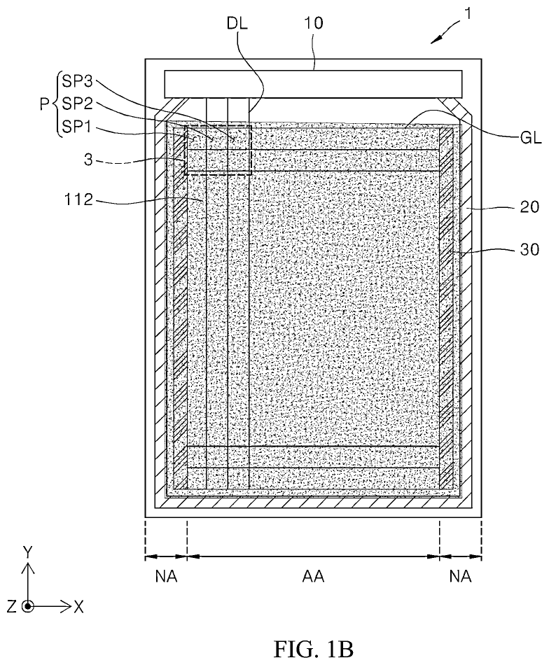

Hereinafter, a display device according to an embodiment of the present disclosure will be described in detail with reference to FIG. 1 to FIG. 5.

FIG. 1A and FIG. 1B are schematic plan views of display devices according to embodiments of the present disclosure, respectively.

An example in which a display device 1 as described below is embodied as an organic light-emitting diode display device will be described. However, the present disclosure is not limited thereto.

The display device 1 may include a display area AA configured to display an image and a non-display area NA surrounding the display area AA. The image is not displayed in the non-display area NA.

In the display area AA, a plurality of data lines DL extending in a first direction and a plurality of gate lines GL extending in a second direction intersecting the first direction may be disposed.

Each sub-pixel SP1, SP2, or SP3 may be disposed in each pixel area as each of intersection areas in which the data lines DL and the gate lines GL interest each other.

The sub-pixels SP1, SP2, and SP3 may be implemented to emit light of the same color such as white (W) light. Alternatively, the sub-pixels SP1, SP2, and SP3 may be implemented to emit light of different colors such as such as red (R), green (G), and blue (B).

For example, a combination of colors of light emitted from the sub-pixels SP1, SP2, and SP3 may be implemented as a combination of red (R), green (G), and blue (B) or a combination of red (R), green (G), blue (B), and white (W).

One pixel P may be configured as a combination of a plurality of sub-pixels SP1, SP2, and SP3 as described above.

Hereinafter, an example in which one pixel P is composed of a first sub-pixel SP1 rendering a first color, a second sub-pixel SP2 rendering a second color, and a third sub-pixel SP3 rendering a third color will be described.

In this case, the first color may be red (R), the second color may be green (G), and the third color may be blue (B). However, the present disclosure is not limited thereto.

A plurality of sub-pixels SP1, SP2, and SP3 may be arranged in a matrix form composed of a plurality of rows and columns.

As used herein, the first direction may be a column direction and is defined as a Y-axis direction. The second direction may be a row direction and may be defined as an X-axis direction.

In the non-display area NA, a plurality of lines and pads supplying various signals and power to the pixel may be disposed.

A data driver circuit (D-IC) 10 may be disposed at one side of the non-display area NA.

The data driver circuit 10 may apply a data signal to the data line DL, and may apply a driving voltage such as a high-potential voltage VDD or a low-potential voltage VSS to the pixel P.

The power line 20 may extend along an edge of the display area AA except for one side of the non-display area NA where the data driver circuit 10 is disposed.

For example, a gate driver 30 for applying a gate signal to the gate line GL may be disposed in a portion of the non-display area NA positioned on each of both opposing sides of the display area AA. The power line 20 capable of applying a voltage to an anode electrode or a cathode electrode in the pixel P may extend along an outer edge of the gate driver 30.

The power line 20 may be a low-potential voltage line capable of applying the low-potential voltage VSS to the cathode electrode of the pixel P. However, the present disclosure is not limited thereto. A high-potential voltage line capable of applying the high-potential voltage VDD to a thin-film transistor of the pixel P may be additionally disposed.

In the display area AA, a plurality of power connection lines 112 electrically connecting the power line 20 and the plurality of sub-pixels SP1, SP2, and SP3 respectively such that the low-potential voltage may be applied to the plurality of sub-pixels SP1, SP2, and SP3 may be disposed.

Referring to FIG. 1A, the power connection line 112 may cover the display area AA.

The power connection lines 112 may be arranged in a grid manner and may extend across the plurality of sub-pixels.

For example, the power connection lines 112 may extend across the plurality of sub-pixels arranged in the first direction, and may extend across the plurality of sub-pixels arranged in the second direction. The power connection lines 112 may be arranged in a grid manner so as to intersect each other to define line openings 112h respectively corresponding to light-emitting areas of the sub-pixels.

An outer side end of the power connection line 112 may be connected to the power line 20 positioned outside the display area AA. Thus, the power line 20 may apply voltage to the power connection line 112.

Referring also to FIG. 1B, the power connection line 112 may cover an entire surface of the display area AA.

For example, the power connection line 112 may be formed in a form of a single integral electrode covering all of the sub-pixels.

An outer side end of the power connection line 112 may be connected to the power line 20 positioned outside the display area AA. Thus, the power line 20 may apply voltage to the power connection line 112.

In this case, the power connection line 112 may be embodied as a transparent line made of a transparent material. Thus, the light from the light-emitting areas of the plurality of sub-pixels may transmit therethrough.

The transparent material may include indium zinc oxide (IZO)-based oxide, or indium tin oxide (ITO)-based oxide. However, the present disclosure is not limited thereto, and the power connection line 112 may be made of various types of transparent materials.

In another embodiment, the plurality of power connection lines 112 may extend in the first direction in which the plurality of data lines DL extend.

The plurality of power connection lines 112 and the plurality of data lines DL may be alternately arranged with each other in the second direction.

One power connection line 112 may extend across a plurality of sub-pixels arranged in the column direction so as to be electrically connected to a portion of the power line 20 disposed adjacent to a lower end of the display area AA.

Accordingly, a plurality of sub-pixels arranged in the same column direction may be electrically connected to the single power connection line 112 and may receive the low-potential voltage from the power line 20 via the single power connection line 112.

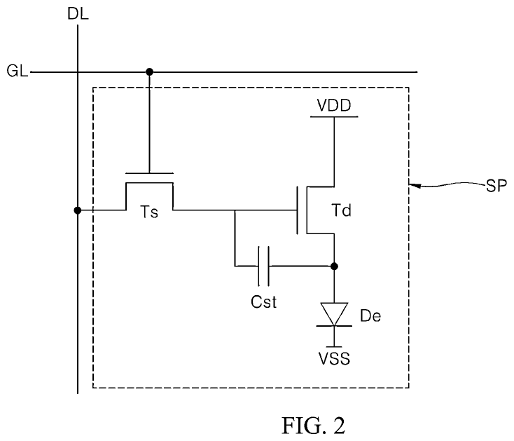

FIG. 2 is a circuit diagram of one sub-pixel of a display device according to an embodiment of the present disclosure.

Each of the sub-pixels SP1, SP2, and SP3 disposed in each of the intersections of the gate lines GL and the data lines DL intersecting each other as described above may include a switching thin-film transistor Ts, a driving thin-film transistor Td, and a storage capacitor Cst, and a light-emitting diode De.

A gate electrode of the switching thin-film transistor Ts may be connected to the gate line GL while a source electrode thereof may be connected to the data line DL.

A gate electrode of the driving thin-film transistor Td may be connected to a drain electrode of the switching thin-film transistor Ts, while a source electrode thereof may be connected to the high-potential voltage VDD.

An anode electrode of the light-emitting diode De may be connected to a drain electrode of the driving thin-film transistor Td, while a cathode electrode thereof may be connected to the low-potential voltage VSS.

One side and the other side of the storage capacitor Cst may be connected to the gate electrode and the drain electrode of the driving thin-film transistor Td, respectively.

The display device 1 including the sub-pixel SP1, SP2, and SP3, each of having a structure of such a circuit diagram may display an image as follows.

The switching thin-film transistor Ts may be turned on based on the gate signal applied via the gate line GL. The data signal applied to the data line DL may be applied to the gate electrode of the driving thin-film transistor Td and one electrode of the storage capacitor Cst via the switching thin-film transistor Ts.

The driving thin-film transistor Td may be turned on based on the data signal so as to control a current flowing through the light-emitting diode De. Thus, an image may be displayed.

The light-emitting diode De may emit light based on a current of the high-potential voltage VDD transmitted through the driving thin-film transistor Td.

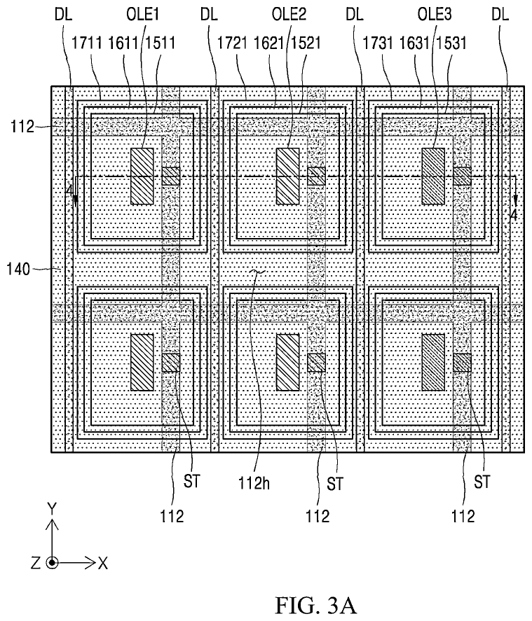

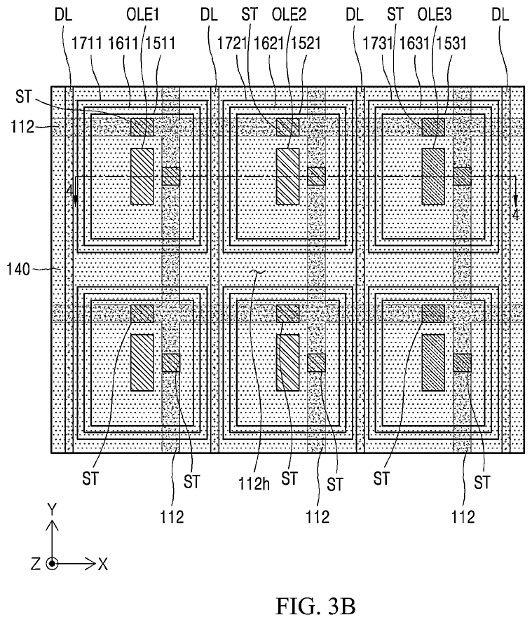

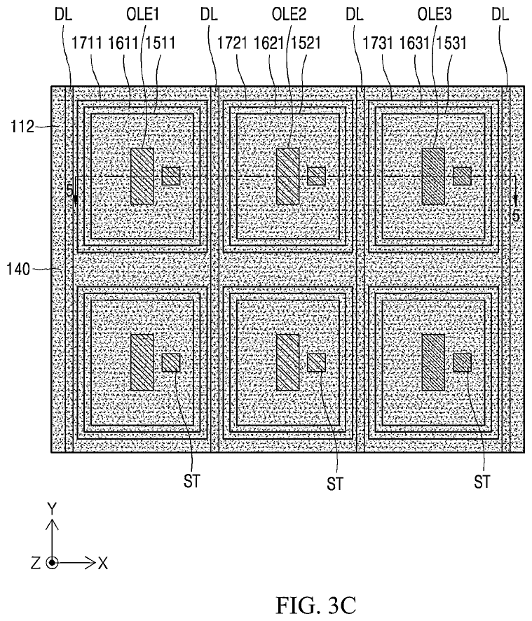

FIG. 3A and FIG. 3B are respectively enlarged plan views of a plurality of sub-pixels of a display device as shown in FIG. 1A according to an embodiment of the present disclosure. FIG. 3C is an enlarged plan view of a plurality of sub-pixels of a display device as shown in FIG. 1B according to still another embodiment of the present disclosure.

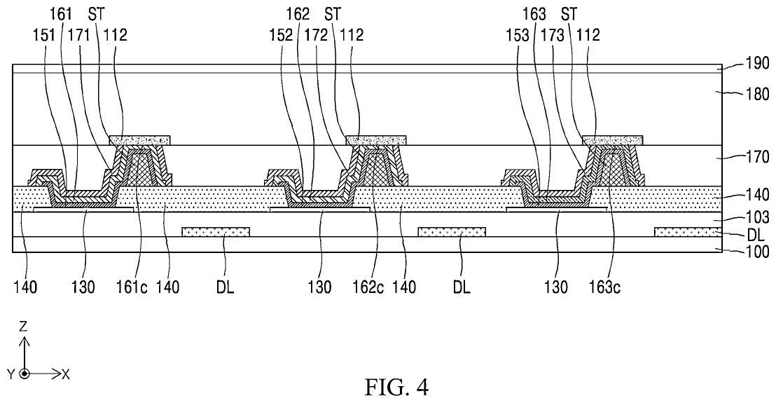

FIG. 4 is a cross-sectional view of a plurality of sub-pixels of a display device as shown in FIG. 3A and FIG. 3B according to an embodiment of the present disclosure.

Specifically, each of FIG. 3A and FIG. 3B is an enlarged view of a plurality of sub-pixels corresponding to an area denoted by a reference numeral 3 in FIG. 1A. FIG. 3C is an enlarged view of a plurality of sub-pixels corresponding to an area denoted by a reference numeral 3 in FIG. 1B.

Hereinafter, one sub-pixel is described by way of example. This description may be equally applied to other sub-pixels when there is no special description.

Referring to FIG. 3A and FIG. 4, a plurality of data lines DL may be disposed on the substrate 100, and an insulating layer 103 may be disposed on the plurality of data lines DL. As shown in FIG. 4, each data line DL is between a pair of adjacent sub-pixels.

In addition, although not shown in the drawing, a thin-film transistor including an active layer, a gate electrode, and source and drain electrodes may be disposed on the substrate 100.

A buffer layer may be additionally disposed between the substrate 100 and the thin-film transistor.

In this case, the thin-film transistor may be a driving thin-film transistor Td or a switching thin-film transistor Ts.

The data line DL and each of the source and drain electrodes may be made of the same material and may be disposed in the same layer. However, the present disclosure is not limited thereto.

An anode electrode layer 130 may be disposed on the insulating layer 103.

The anode electrode layer 130 may be electrically connected to the source and drain electrodes of the thin-film transistor.

A bank layer 140 may be formed on the anode electrode layer 130.

The bank layer 140 may function as a pixel definition layer that defines each of the plurality of sub-pixels SP1, SP2, and SP3.

Therefore, the bank layer 140 as the pixel definition layer may be disposed between adjacent ones of the sub-pixels SP1, SP2, and SP3 so as to define a boundary between adjacent ones of the sub-pixels SP1, SP2, and SP3 rendering different colors, and to prevent color mixing of light beams respectively emitted from adjacent ones of the sub-pixels SP1, SP2, and SP3.

The bank layer 140 may include an opening 1402 opened to expose a partial area of the anode electrode layer 130.

The opening 1402 formed in the first sub-pixel SP1 may define a first light-emitting area OLE1. The opening 1402 formed in the second sub-pixel SP2 may define a second light-emitting area OLE2. In addition, the opening 1402 formed in the third sub-pixel SP3 may define a third light-emitting area OLE3.

A structure ST protruding upwardly so as to have a predetermined height may be disposed on the bank layer 140.

The structure ST may be formed to have an island structure, and may be formed in a tapered shape in which a width in a left and right direction (e.g., horizontal direct) thereof increase as the structure ST extends from a bottom to a top thereof.

The structure ST is formed in the tapered shape in this way, such that even when an organic light-emissive layer, a cathode electrode layer, and a passivation layer, which will be described later are formed on the structure ST, each of the organic light-emissive layer, the cathode electrode layer, and the passivation layer may not be broken but may extend continuously across each sub-pixel.

The structure ST may be made of an organic material. The material is not particularly limited.

The structure ST may be made of a material different from that of the bank layer 140 and may be formed in a separate process from a process in which the bank layer 140 is formed. However, the present disclosure is not limited thereto.

For example, the structure ST may be integrally formed with the bank layer 140 and may be made of the same material as that of the bank layer 140. In this case, the structure ST and the bank layer 140 may be formed in the same patterning process.

In this case, the bank layer 140 may be formed to include the structure ST in a patterning process using a halftone mask.

An entire area of the structure ST may be disposed on the bank layer 140.

However, the present disclosure is not limited thereto, and only a partial area of the structure ST may be disposed on the bank layer 140 and the remaining area thereof and the bank layer 140 may be disposed on the same plane.

The structure ST may be disposed in one side portion of each light-emitting area and may be positioned in each sub-pixel without overlapping the one side of the light-emitting area. However, the present disclosure is not limited thereto.

Referring to FIG. 3B, the structure ST may be formed in one side portion of each light-emitting area, and a further structure ST may be formed in another side portion thereof.

Accordingly, the structure ST may extend discontinuously along an outer area of each light-emitting area. However, a construction of the structure ST is not particularly limited.

Alternatively, the structure ST may extend continuously along the outer area of each light-emitting area.

For example, the structure ST of the first sub-pixel SP1 may extend continuously formed along the outer area of the first light-emitting area OLE1. The structure ST of the second sub-pixel SP2 may extend continuously along the outer area of the second light-emitting area OLE2. The structure ST of the third sub-pixel SP3 may extend continuously along the outer area of the third light-emitting area OLE3.

The organic light-emissive layer, the cathode electrode layer, and the passivation layer may be sequentially stacked on the bank layer 140 so as to cover the structure ST. That is, a first portion of the first organic light-emissive layer 151 is over the anode electrode layer 130, a first portion of the first cathode electrode layer 161 is over the first portion of the first organic light-emissive layer 151 and the anode electrode layer, and a first portion of the first passivation layer 171 is over the first portion of the first cathode electrode layer 161, the first portion of the first organic light-emissive layer 151, and the anode electrode layer.

Specifically, a first organic light-emissive layer 151 rendering a first color, a first cathode electrode layer 161, and a first passivation layer 171 may be disposed in the first sub-pixel SP1. In the second sub-pixel SP2, a second organic light-emissive layer 152 rendering a second color, a second cathode electrode layer 162, and a second passivation layer 172 may be disposed. A third organic light-emissive layer 153 rendering a third color, a third cathode electrode layer 163, and a third passivation layer 173 may be disposed in the third sub-pixel SP3.

In this case, organic light-emissive layers, cathode electrode layers, and passivation layers of sub-pixels adjacent to each other may be disconnected from each other.

As used herein, the disconnection between two components may mean that the two components are physically separated from each other, and may mean that the two components are not electrically connected to each other.

However, even when the two components are disconnected from each other, the two components may be electrically connected to each other in an indirect way via another middle medium.

For example, the first organic light-emissive layer 151 and the second organic light-emissive layer 152 adjacent to each other may be disconnected from each other. The second organic light-emissive layer 152 and the third organic light-emissive layer 153 adjacent to each other may be disconnected from each other. The third organic light-emissive layer 153 and the first organic light-emissive layer 151 adjacent to each other may be disconnected from each other.

Moreover, the first cathode electrode layer 161 and the second cathode electrode layer 162 adjacent to each other may be disconnected from each other. The second cathode electrode layer 162 and the third cathode electrode layer 163 adjacent to each other may be disconnected from each other. The third cathode electrode layer 163 and the first cathode electrode layer 161 adjacent to each other may be disconnected from each other.

Moreover, the first passivation layer 171 and the second passivation layer 172 adjacent to each other may be disconnected from each other. The second passivation layer 172 and the third passivation layer 173 adjacent to each other may be disconnected from each other.

The third passivation layer 173 and the first passivation layer 171 adjacent to each other may be disconnected from each other.

The outermost boundary 1511 of the first organic light-emissive layer 151, the outermost boundary 1611 of the first cathode electrode layer 161, and the outermost boundary 1711 of the first passivation layer 171 may be disposed in the first sub-pixel SP1 formed between adjacent data lines DL.

Accordingly, the first organic light-emissive layer 151, the first cathode electrode layer 161, and the first passivation layer 171 may not overlap (e.g., non-overlapping) the data line DL in the vertical direction.

The first cathode electrode layer 161 may include a material having a relatively superior step coverage than that of a material of the first organic light-emissive layer 151, and accordingly, an end of the first cathode electrode layer 161 may be positioned outwardly of an end of the first organic light-emissive layer 151. That is, the end of the first cathode electrode layer 161 extends past the end of the first organic light-emissive layer 151.

Therefore, the first cathode electrode layer 161 may be formed to cover an entirety of the first organic light-emissive layer 151 such that an outermost boundary 1611 of the first cathode electrode layer 161 may be positioned outwardly of an outermost boundary 1511 of the first organic light-emissive layer 151. Thus, the outermost boundary 1511 of the first organic light-emissive layer 151 is inset from the outermost boundary 1611 of the first cathode electrode layer 161.

The first passivation layer 171 may include a material having a step coverage relatively superior to that of a material of the first cathode electrode layer 161, and accordingly, an end of the first passivation layer 171 may be positioned outwardly the end of the first cathode electrode layer 161. That is, the end of the first passivation layer 171 extends past the end of the first cathode electrode layer 161.

Therefore, the first passivation layer 171 may be formed to cover an entirety of the first cathode electrode layer 1611 such that an outermost boundary 1711 of the first passivation layer 171 may be positioned outwardly of the outermost boundary 1611 of the first cathode electrode layer 161. Thus, the outermost boundary 1611 of the first cathode electrode layer 161 is inset from the outermost boundary 1711 of the first passivation layer 171.

Moreover, an outermost boundary 1521 of the second organic light-emissive layer 152, an outermost boundary 1621 of the second cathode electrode layer 162, and an outermost boundary 1721 of the second passivation layer 172 may be disposed in the second sub-pixel SP2 formed between adjacent data lines DL.

Accordingly, the second organic light-emissive layer 152, the second cathode electrode layer 162, and the second passivation layer 172 may not overlap (e.g., non-overlapping) the data line DL in the vertical direction.

The second cathode electrode layer 162 may include a material having a relatively superior step coverage than that of a material of the second organic light-emissive layer 152, and accordingly, an end of the second cathode electrode layer 162 may be positioned outwardly of an end of the second organic light-emissive layer 152. That is, the end of the second cathode electrode layer 162 extends past the end of the second organic light-emissive layer 152.

Therefore, the second cathode electrode layer 162 may be formed to cover an entirety of the second organic light-emissive layer 152 such that the outermost boundary 1621 of the second cathode electrode layer 162 may be positioned outwardly of the outermost boundary 1521 of the second organic light-emissive layer 152.

The second passivation layer 172 may include a material having a relatively superior step coverage than that of a material of the second cathode electrode layer 162, and accordingly, an end of the second passivation layer 172 may be positioned outwardly of the end of the second cathode electrode layer 162. That is, the end of the second passivation layer 172 extends past the end of the second cathode electrode layer 162.

Therefore, the second passivation layer 172 may be formed to cover an entirety of the second cathode electrode layer 162 such that the outermost boundary 1721 of the second passivation layer 172 may be positioned outwardly of the outermost boundary 1621 of the second cathode electrode layer 162.

Moreover, an outermost boundary 1531 of the third organic light-emissive layer 153, an outermost boundary 1631 of the third cathode electrode layer 163, and an outermost boundary 1731 of the third passivation layer 173 may be disposed in the third sub-pixel SP3 formed between adjacent data lines DL.

Accordingly, the third organic light-emissive layer 153, the third cathode electrode layer 163, and the third passivation layer 173 may not overlap (e.g., non-overlapping) the data line DL in the vertical direction.

The third cathode electrode layer 163 may include a material having a relatively superior step coverage than that of a material of the third organic light-emissive layer 153, and accordingly, an end of the third cathode electrode layer 163 may be positioned outwardly of an end of the third organic light-emissive layer 153. That is, the end of the third cathode electrode layer 163 extends past the end of the third organic light-emissive layer 153.

Therefore, the third cathode electrode layer 163 may be formed to cover an entirety of the third organic light-emissive layer 153 such that the outermost boundary 1631 of the third cathode electrode layer 163 may be positioned outwardly of the outermost boundary 1531 of the third organic light-emissive layer 153.

The third passivation layer 173 may include a material having a relatively superior step coverage than that of a material of the third cathode electrode layer 163, and accordingly, an end of the third passivation layer 173 may be positioned outwardly of the end of the third cathode electrode layer 163. That is, the end of the third passivation layer 173 extends past the end of the third cathode electrode layer 163.

Therefore, the third passivation layer 173 may be formed to cover an entirety of the third cathode electrode layer 163 such that the outermost boundary 1731 of the third passivation layer 173 may be positioned outwardly of the outermost boundary 1631 of the third cathode electrode layer 163.

When the cathode electrode layers adjacent to each other are not disconnected from each other but are integral with each other into a single electrode structure which continuously extends so as to cover an entirety of the display area, the cathode electrode layer is disposed to overlap the data line, such that an unintended parasitic capacitor may be generated between the cathode electrode layer and the data line.

When the parasitic capacitor is generated in this way, the RC delay may increase.

The RC delay refers to a value obtained by multiplying a resistance R and a capacitance C by each other, and means decrease in an electrical transmission rate.

Therefore, when the RC delay increases, the reduction in the electrical transmission rate increases. Thus, the display device cannot operate at a high-speed.

However, according to an embodiment of the present disclosure, the cathode electrode layer and the data line may be disposed so as not to overlap with each other (e.g., non-overlapping) in the vertical direction, thereby reducing the occurrence of the parasitic capacitor that may be generated between the cathode electrode layer and the data line.

Accordingly, according to an embodiment of the present disclosure, greatly reducing the occurrence of the RC delay may allow the display device to operate at the high speed.

In an area corresponding to the opening 1402 of the first sub-pixel SP1 of the bank layer 140, the first organic light-emissive layer 151, the first cathode electrode layer 161, and the first passivation layer 171 may be sequentially stacked. An area where the anode electrode layer 130, the first organic light-emissive layer 151, and the first cathode electrode layer 161 overlap each other may be a first light-emissive area OLE1 emitting light.

Moreover, in an area corresponding to the opening 1402 of the second sub-pixel SP2 of the bank layer 140, the second organic light-emissive layer 152, the second cathode electrode layer 162, and the second passivation layer 172 may be sequentially stacked. An area where the anode electrode layer 130, the second organic light-emissive layer 152, and the second cathode electrode layer 162 overlap each other may be a second light-emissive area OLE2 emitting light.

Moreover, in an area corresponding to the opening 1402 of the third sub-pixel SP3 of the bank layer 140, the third organic light-emissive layer 153, the third cathode electrode layer 163, and the third passivation layer 173 may be sequentially stacked. An area where the anode electrode layer 130, the third organic light-emissive layer 153, and the third cathode electrode layer 163 overlap each other may be a third light-emissive area OLE3 emitting light.

The first organic light-emissive layer 151, the second organic light-emissive layer 152, and the third organic light-emissive layer 153 may include light-emissive layers (EML) that emit red, green, and blue light beams, respectively. The light-emissive layer may be made of a phosphorescent material or a fluorescent material. A specific material thereof is not particularly limited.

For example, a hole injection layer (HIL) and/or a hole transporting layer (HTL) may be additionally disposed between the anode electrode layer 130 and the organic light-emissive layer (EML). An electron transport layer (ETL) and/or an electron injection layer (HIL) may be disposed between the light-emissive layer (EML) and the cathode electrode layer.

When the organic light-emissive layers adjacent to each other are not disconnected from each other but are integral with each other into a single structure which continuously extends so as to cover an entirety of the display area, light which is generated from the light-emissive area but does not escape to the outside may continue to be reflected from an interface, propagate to a side surface, and then disappear.

However, according to an embodiment of the present disclosure, the organic light-emissive layers of adjacent sub-pixels are disconnected from each other, the cathode electrode layers of adjacent sub-pixels are disconnected from each other, and the passivation layers of adjacent sub-pixels are disconnected from each other. Thus, a travel path of the light from the organic light-emissive layer changes at the disconnected end such that the light may escape to the outside.

Accordingly, according to an embodiment of the present disclosure, light extraction efficiency from the organic light-emissive layer may be further improved based on occurrence of an out-coupling phenomenon.

Moreover, according to an embodiment of the present disclosure, the organic light-emissive layers of adjacent sub-pixels are disconnected from each other, the cathode electrode layers of adjacent sub-pixels are disconnected from each other, and the passivation layers of adjacent sub-pixels are disconnected from each other. Thus, occurrence of lateral leakage current in the organic light-emissive layer which may occur when the organic light-emissive layers are connected to each other and extend continuously may be reduced.

As described above, the structure ST is formed in the tapered shape. Thus, each of the organic light-emissive layer, the cathode electrode layer, and the passivation layer formed on the structure ST may not be broken but may extend continuously in each sub-pixel.

However, a partial area of the passivation layer 171 disposed on the structure ST (e.g., overlapping the structure ST) may be opened to expose a portion of the cathode electrode layer. That is, the passivation layer 171 includes a first portion and a second portion where the first portion of the passivation layer 171 is on a first portion of the cathode electrode layer 171 in the opening of the bank layer 140 and the second portion of the passivation layer 171 is on a second portion of the organic light-emissive layer 161 and the structure ST without being between the second portion of the cathode electrode layer 171 and the portion of the power connection line 112 that is in contact with the second portion of the cathode electrode layer 161.

This will be further described later.

A first capping layer 170 may be disposed on the bank layer 140.

The first capping layer 170 may be made of an organic material. However, the present disclosure is not limited thereto.

The first capping layer 170 may act as a planarization layer, and accordingly, the first capping layer 170 may be formed to have a thickness sufficient so as to cover the bank layer 140 and the first passivation layer 171.

Therefore, the first capping layer 170 and the structure ST may be formed in the same layer based on the bank layer 140.

The first capping layer 170 formed so as to cover the first organic light-emissive layer 151, the first cathode electrode layer 161, and the first passivation layer 171 which are sequentially stacked may cover the first passivation layer 171, while a portion of each of the first passivation layer 171 and the first capping layer 170 corresponding to the structure ST may be removed.

Specifically, a portion of each of the first passivation layer 171 and the first capping layer 170 corresponding to (e.g., overlapping) an upper surface of structure ST may be removed to define an open area

In this case, the first passivation layer 171 and the first capping layer 170 may be formed to cover a side surface of the structure ST but not the upper surface of the structure ST.

A width in the left and right direction of the opened area of each of the first passivation layer 171 and the first capping layer 170 obtained via the removal of the portion thereof corresponding to the upper surface of the structure ST may be larger than a width in the left and right direction of the upper surface of the structure ST.

For example, the uppermost surface of the first capping layer 170 may be coplanar with an end of the uppermost surface of the first passivation layer 171, specifically, the uppermost level of the first passivation layer 171.

In addition, the upper surface of the first capping layer 170 may be coplanar with the upper surface of the first cathode electrode layer 161 exposed through the open area of the first passivation layer 171. That is, the upper surface of the first capping layer 170 may be coplanar with a portion of the cathode electrode layer 161 that is in contact with the power connection line 112

Accordingly, the upper surface of the first capping layer 170 may be coplanar with the upper surface of the end of the first passivation layer 171 and the upper surface of the first cathode electrode layer 161.

In the present disclosure, the phrase “A being coplanar with B” may mean that a step is not formed between A and B, but A and B define a planarized surface.

In this way, a portion of the first cathode electrode layer 161 exposed through the open area obtained by removing the portion of each of the first capping layer 170 and the first passivation layer 171 disposed on the structure ST may act as a first cathode contact 161c.

The first cathode contact 161c refers to an exposed partial area (or portion) of the first cathode electrode layer 161, and may not be physically distinguished from a main area of the first cathode electrode layer 161 but may be conceptually distinguished therefrom.

The power connection line 112 disposed to overlap the structure ST in a vertical direction may be formed on the first capping layer 170 formed as described above,

The power connection line 112 may be disposed so as to directly contact the first cathode contact 161c, and may be electrically connected to the first cathode electrode layer 161 via the first cathode contact 161c.

As described above, the upper surface of the first cathode contact part 161c and the upper surface of the first capping layer 170 are coplanar with each other, such that the power connection line 112 may more stably contact the first cathode contact part 161c.

For an operation of each of the sub-pixels SP1, SP2, and SP3, the low-potential voltage VSS should be applied to the cathode electrode layer.

However, according to the embodiment of the present disclosure, the cathode electrode layers respectively included in adjacent ones of the sub-pixels SP1, SP2, and SP3 are disconnected from each other. For this reason, the low-potential voltage VSS may be applied to each of the cathode electrode layers respectively included in the sub-pixels SP1, SP2, and SP3 via the electrical connection between the power connection line 112 and the cathode contact.

When the power connection lines 112 are arranged in the grid manner, a partial area of the power connection line 112 may not overlap the data line DL in the vertical direction, while the remaining partial area thereof may overlap the data line DL in the vertical direction.

However, according to the present disclosure, the power connection line 112 is formed on the first capping layer 170, and the data line DL is disposed under the bank layer 140. Thus, the bank layer 140 and the first capping layer 170 may be disposed between the power connection line 112 and the data line DL.

Accordingly, the distance between the power connection line 112 and the data line DL may be increased, thereby reducing the parasitic capacitor that may occur between the power connection line 112 and the data line DL overlapping each other in the vertical direction, and thus reducing the occurrence of the decrease in the electrical transmission rate (the RC delay).

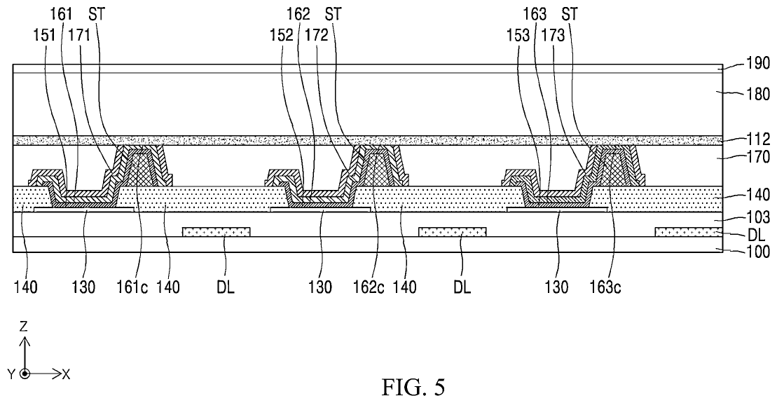

Further, referring to FIG. 3C and FIG. 5 illustrating another embodiment, the power connection line 112 disposed on the first capping layer 170 may be formed in the form of the single integral electrode covering an entirety of the display area AA.

When, in this way, the power connection line 112 is formed in the form of the single integral electrode covering an entire surface of the display area AA so as to cover the plurality of sub-pixels, the power connection line 112 may be made of a transparent material.

Even in this case, the bank layer 140 and the first capping layer 170 may be disposed between the power connection line 112 and the data line DL to increase the distance between the power connection line 112 and the data line DL, thereby reducing the generation of the parasitic capacitor between the power connection line 112 and the data line DL, and thus reducing the occurrence of the decrease in the electrical transmission rate (the RC delay).

A second capping layer 180 and a passivation layer 190 may be additionally disposed on the power connection line 112.

In this case, the second capping layer 180 may be made of an organic material, and may be made of the same material as that of the first capping layer 170. However, the present disclosure is not limited thereto, and the second capping layer 180 and the first capping layer 170 may be made of different materials.

The connection structure between the first cathode contact 161c and the power connection line 112 in the first sub-pixel SP1 as described above may be equally applied to each of the second sub-pixel SP2 and the third sub-pixel SP3. Thus, redundant descriptions thereof are omitted.

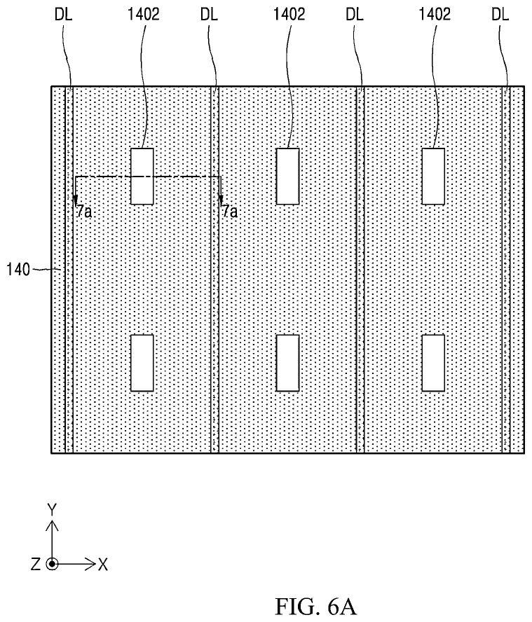

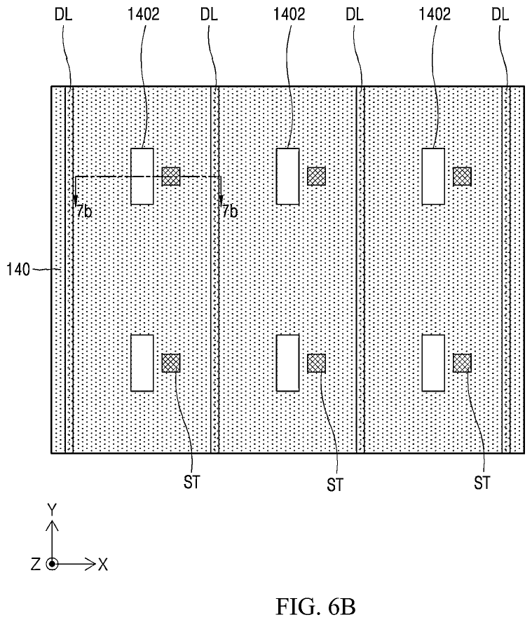

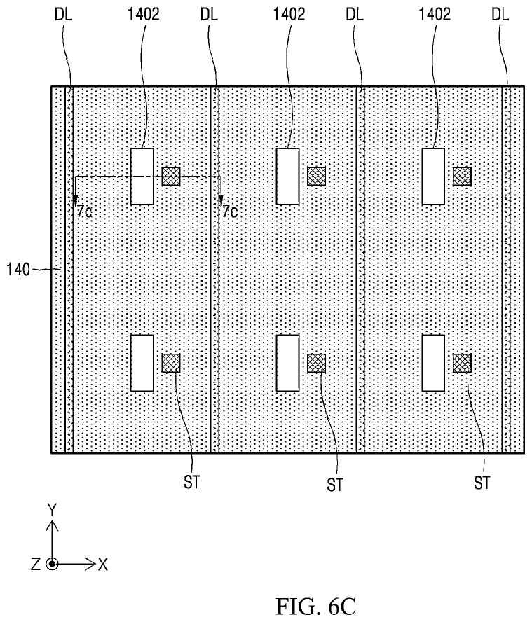

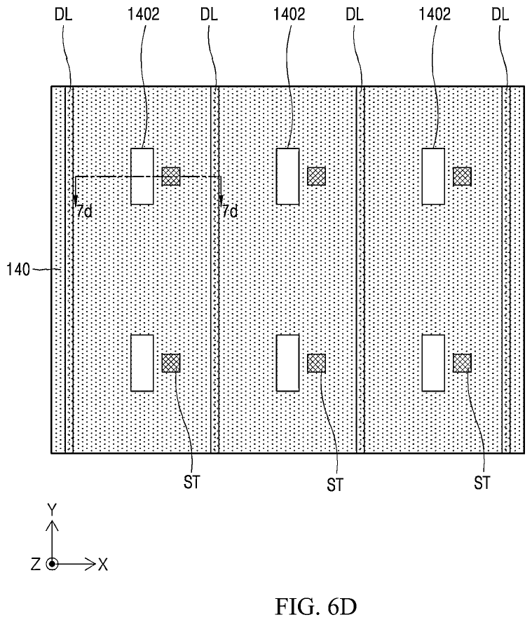

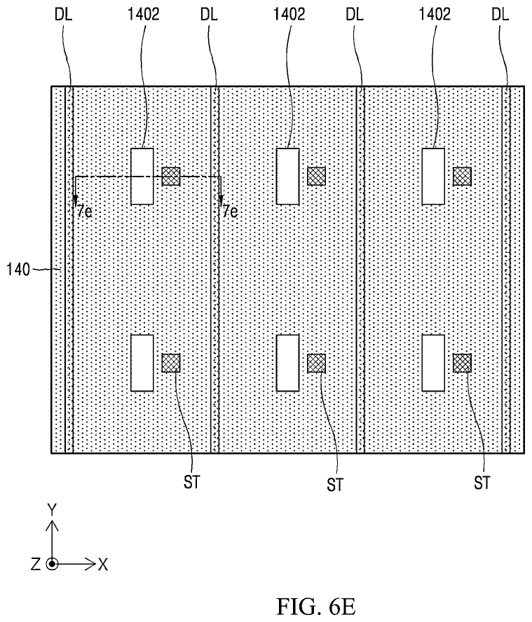

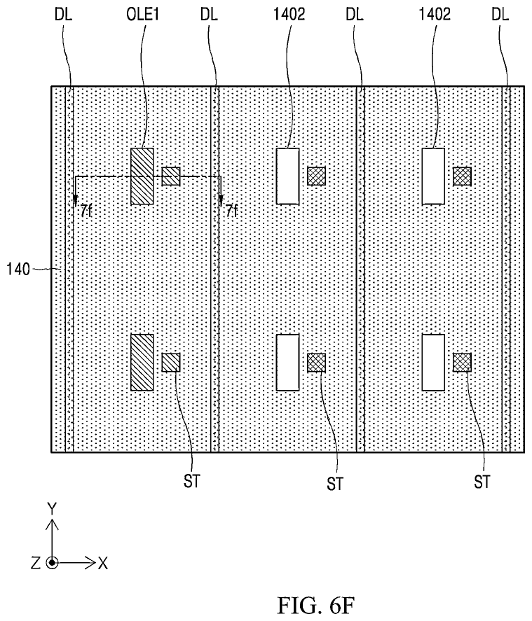

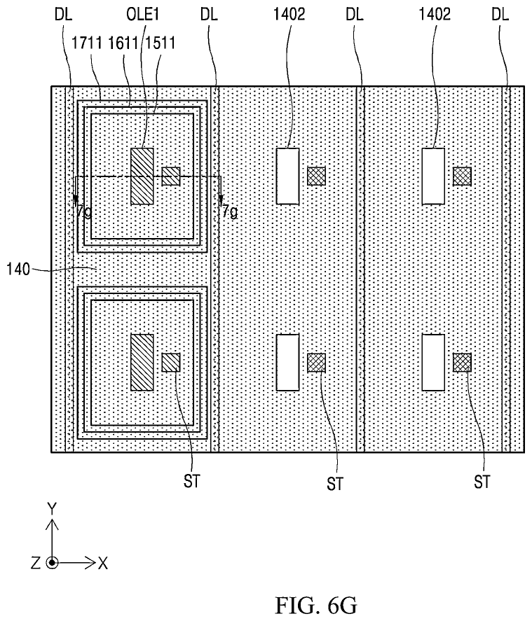

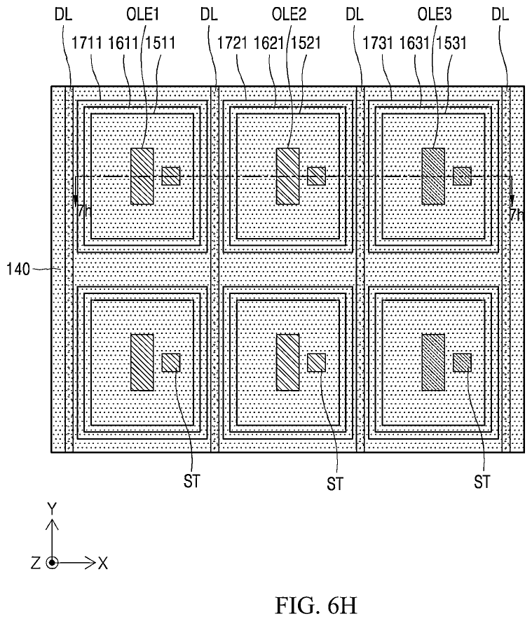

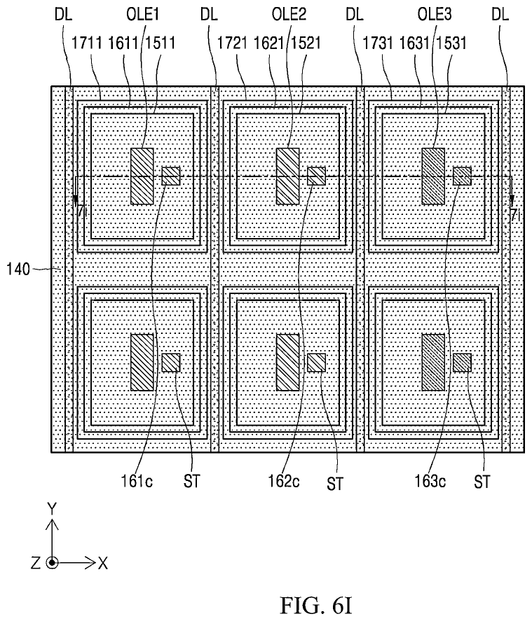

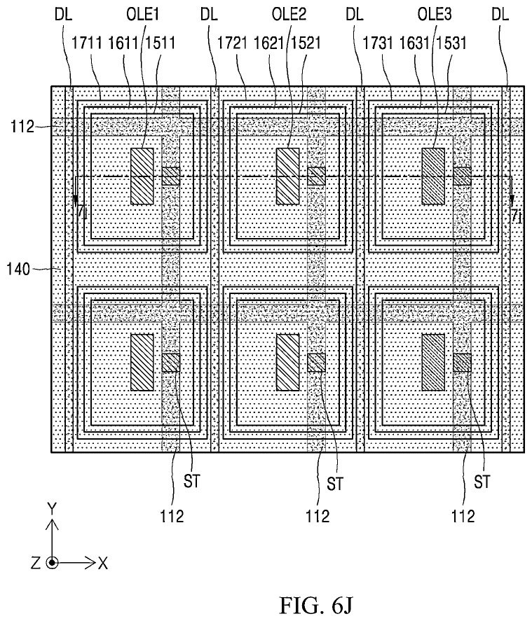

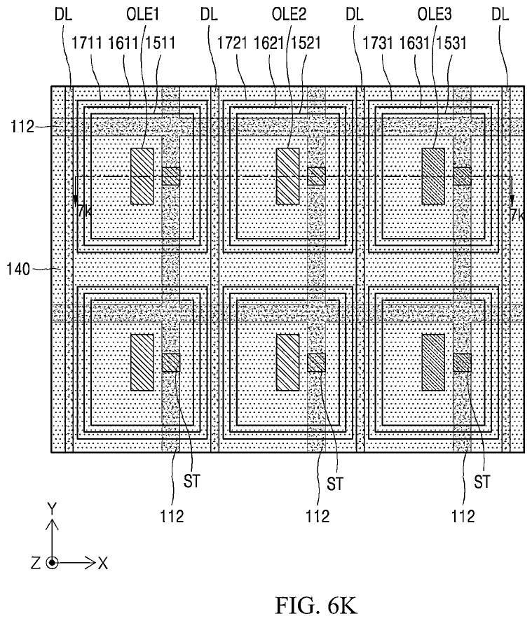

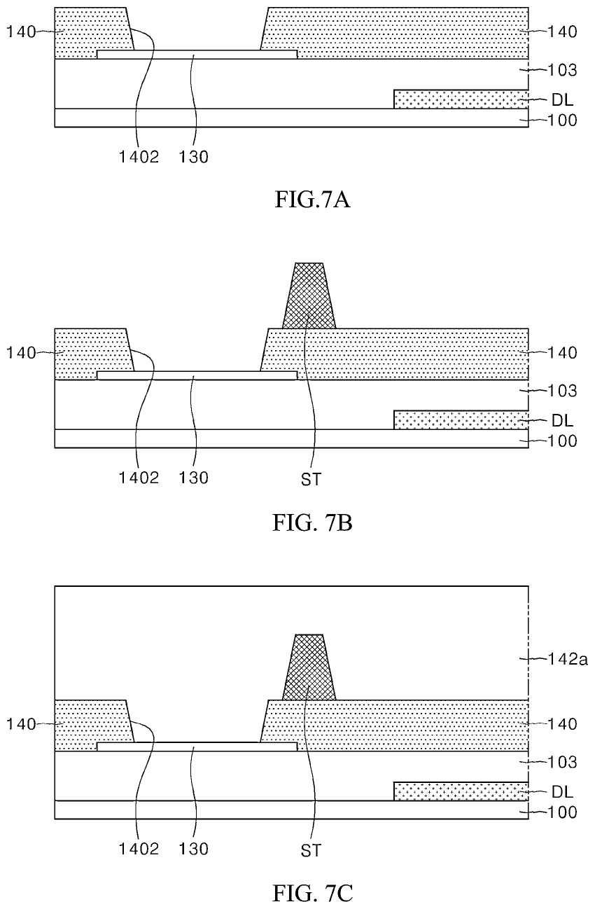

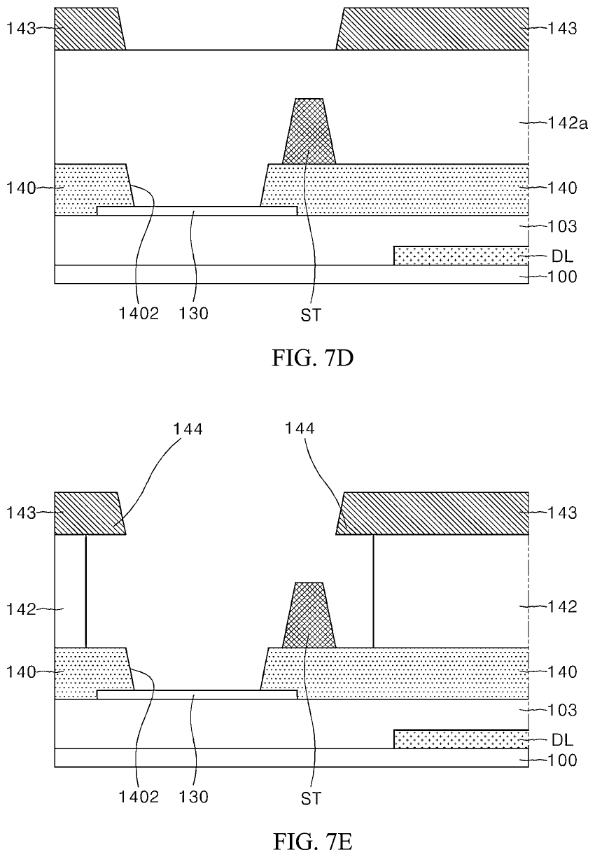

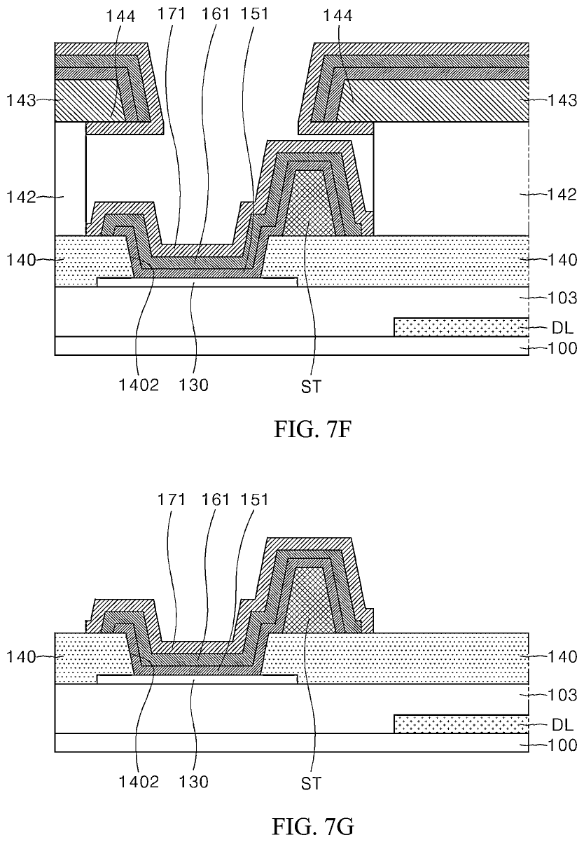

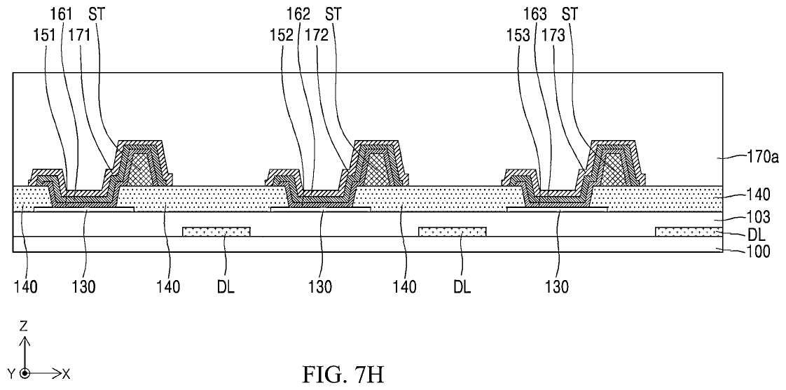

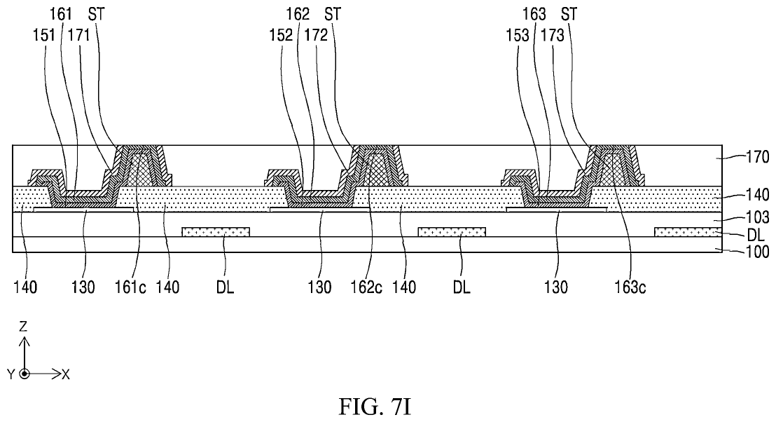

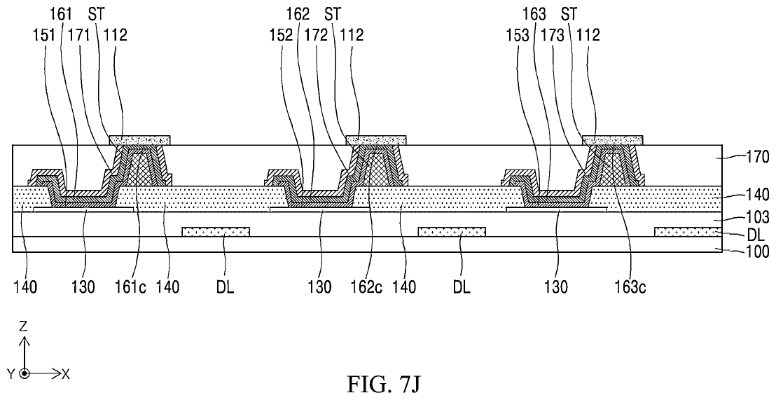

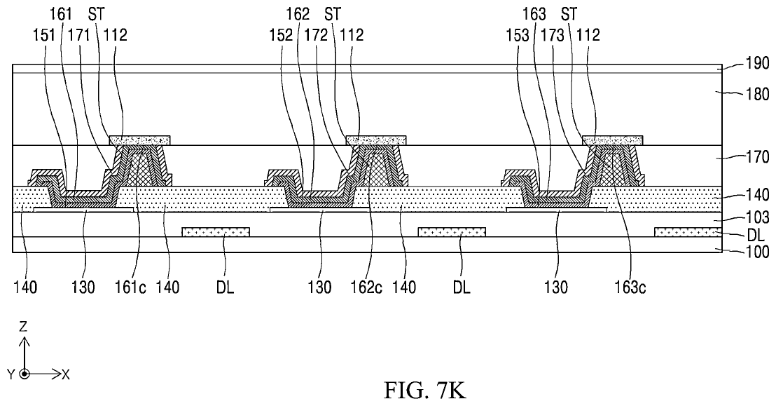

FIG. 6A to FIG. 6K are plan views of a plurality of sub-pixels in a process of manufacturing a display device according to an embodiment of the present disclosure. FIG. 7A to FIG. 7K are cross-sectional views respectively corresponding to FIG. 6A to FIG. 6K according to an embodiment of the present disclosure.

For the convenience of illustration, each of the plan views of FIG. 6A to FIG. 6K shows only some components as shown in each of the cross-sectional views of FIG. 7A to FIG. 7K.

A scheme for forming a pattern in each of layers as described below may employ a technique performed by a person skilled in the art, such as a photolithography process including deposition, photoresist application (PR coating), exposure, development, etching, and photoresist stripping (PR strip). A detailed description thereof will be omitted.

For example, depositing a metal material may be performed using sputtering.

Depositing a semiconductor or insulating film may be performed using PECVD (Plasma Enhanced Vapor Deposition). Dry etching or wet etching may be selected based on a material subjected to the etching. A technique performed by a person skilled in the art may be applied thereto.

Referring to FIG. 6A and FIG. 7A, the plurality of data lines DL may be formed on the substrate 100, and the insulating layer 103 may be formed to cover the plurality of data lines DL.

Then, the plurality of anode electrode layers 130 respectively positionally corresponding to the sub-pixels and included therein may be formed on the insulating layer 103.

In addition, the bank layer 140 including a plurality of second openings 1402 respectively exposing portions of the plurality of anode electrode layers 130 may be formed.

A pixel definition PDL may be defined by the opening 1402 of the bank layer 140 and may be formed in each sub-pixel.

The bank layer 140 may be formed to cover the entirety of the display area AA <201> except for areas corresponding to the plurality of openings 1402.

Referring to FIG. 6B and FIG. 7B, a plurality of structures ST may be formed on the bank layer 140 so as to be respectively positioned in the plurality of sub-pixels.

The structure ST may protrude upwardly so as to have a predetermined thickness and thus may serve as a contact spacer, and may be formed in a tapered shape.

Referring to FIG. 6C and FIG. 7C, a first protective film 142a may be formed to cover an entirety of the substrate 100.

The first protective film 142a may include a fluorine-based material.

For example, the first protective film 142a may be made of a fluoropolymer material having a carbon-carbon backbone and a functional group containing a large amount of fluorine (F).

According to an example of the present disclosure, a chemical structure of the fluoropolymer material having the functional group containing a large amount of fluorine (F) has a following [Chemical Formula 1]:

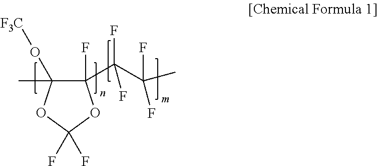

As shown in the [Chemical Formula 1], the fluoropolymer used as a material of the protective film has the functional group containing a large amount of fluorine (F).

The fluoropolymer having the functional group containing a large amount of fluorine (F) may have orthogonality.

The orthogonality may be understood as a property in which two elements are independent of each other.

Accordingly, the first protective film 142a may have both hydrophobic properties with low affinity to water and oleophobic properties with low affinity to oil.

Due to this orthogonality, the first protective film 142a may block a path through which moisture permeates due to characteristics of rejecting the moisture.

Moreover, the first protective film 142a may be less affected by a developer containing an organic solvent used in a process step. This may reduce damage to an organic material by the organic solvent.

Referring to FIG. 6D and FIG. 7D, a first photoresist film 143 may be formed on the first protective film 142a.

For example, the first photoresist film 143 may be formed by depositing a photoresist material and patterning the same so as to have a predetermined pattern.

The first photoresist film 143 may have the predetermined pattern in which the first photoresist film 143 has an opening in an area corresponding to the first sub-pixel SP1, while the first photoresist film 143 does not have an opening in an area corresponding to each of the second sub-pixel SP2 and the third sub-pixel SP3 but covers the second sub-pixel SP2 and the third sub-pixel SP3.

Specifically, the first photoresist film 143 may be formed in the pattern such that a portion of an upper surface of the first protective film 142a corresponding the opening 1402 of the first sub-pixel SP1 may be exposed.

Referring to FIG. 6E and FIG. 7E, a first protective layer 142 having a predetermined pattern may be formed by patterning the underlying first protective film 142a using the first photoresist film 143 as a photo mask.

The first protective layer 142 formed in this way may not cover the opening 1402 of the bank layer 140 so as to be exposed to the outside. Thus, the structure ST may be exposed to the outside.

In this case, as the first protective layer 142 is positioned inwardly of the first photoresist film 143 disposed thereon, the first photoresist film 143 may have an overhang structure on the first protective layer 142.

In this case, as the first protective layer 142 is positioned inwardly of the first photoresist layer 143 disposed thereon, the first photoresist layer 143 may provide an overhang structure on the first protective layer 142.

Accordingly, the first photoresist layer 143 may include an overhang 144 protruding inwardly of the first protective layer 142.

Referring to FIG. 6F and FIG. 7F, the first organic light-emissive layer 151 rendering the first color, the first cathode electrode layer 161, and the first passivation layer 171 may be sequentially stacked.

For example, the first organic light-emissive layer 151 rendering the first color, the first cathode electrode layer 161, and the first passivation layer 171 may be sequentially deposited on an entire surface of the substrate 100.

Accordingly, the first organic light-emissive layer 151, the first cathode electrode layer 161, and the first passivation layer 171 may be sequentially stacked in the opening 1402 of the bank layer 140. The first organic light-emitting layer 151, the first cathode electrode layer 161, and the first passivation layer 171 stacked in this way may extend to cover the structure ST and extend continuously.

However, each of the first organic light-emitting layer 151, the first cathode electrode layer 161, and the first passivation layer 171 may be broken or discontinuous due to the first photoresist film 143 having an overhang structure including the overhang 144 on the first protective layer 142.

The first cathode electrode layer 161 may include a material having a relatively superior step coverage than that of a material of the first organic light-emissive layer 151, and accordingly, an end of the first cathode electrode layer 161 may be positioned outwardly of an end of the first organic light-emissive layer 151.

Therefore, the first cathode electrode layer 161 may be formed to cover an entirety of the first organic light-emissive layer 151 such that an outermost boundary 1611 of the first cathode electrode layer 161 may be positioned outwardly of an outermost boundary 1511 of the first organic light-emissive layer 151.

The first passivation layer 171 may include a material having a step coverage relatively superior to that of a material of the first cathode electrode layer 161, and accordingly, an end of the first passivation layer 171 may be positioned outwardly the end of the first cathode electrode layer 161.

Therefore, the first passivation layer 171 may be formed to cover an entirety of the first cathode electrode layer 161 such that an outermost boundary 1711 of the first passivation layer 171 may be positioned outwardly of the outermost boundary 1611 of the first cathode electrode layer 161.

The first organic light-emitting layer 151, the first cathode electrode layer 161, and the first passivation layer 171 may be sequentially stacked in the opening 1402. Thus, an area in which the first organic light-emitting layer 151, the first cathode electrode layer 161, and the anode electrode layer 130 overlap each other may be embodied as the first light-emitting area OLE1.

Referring to FIG. 6G and FIG. 7G, the first protective layer 142 and the first photoresist layer 143 may be removed.

Specifically, the first photoresist film 143, the first organic light-emissive layer 151, the first cathode electrode layer 161, and the first passivation layer 171 stacked on the first protective layer 142 may be removed together in a process of stripping the first protective layer 142.

Referring to FIG. 6H and FIG. 7H, the process applied to the first sub-pixel SP1 as described in FIG. 6C to FIG. 6G and FIG. 7C to FIG. 7G may be equally performed on each of the second sub-pixel SP2 and the third sub-pixel SP3.

Specifically, a second protective layer and a second photoresist film may be formed to expose the opening 1402 corresponding to the second sub-pixel SP2. The second organic light-emissive layer 152 rendering the second color, the second cathode electrode layer 162, and the second passivation layer 172 may be sequentially stacked. Then, the second protective layer and the second photoresist film may be removed.

Accordingly, the second light-emissive area OLE2 of the second sub-pixel SP2 may be formed. The second organic light-emissive layer 152, the second cathode electrode layer 162, and the second passivation layer 172 may be sequentially formed on the structure ST of the second sub-pixel SP2.

After the process on the second sub-pixel SP2 has been performed in this manner, a third protective layer and a third photoresist film may be formed to expose the first opening 1401 and the opening 1402 corresponding to the third sub-pixel SP3. The third organic light-emissive layer 153 rendering the third color, the third cathode electrode layer 163, and the third passivation layer 173 may be sequentially stacked. Then, the third protective layer and the third photoresist film may be removed.

Accordingly, the third light-emissive area OLE3 of the third sub-pixel SP3 may be formed. the power connection line 112 extending across the third sub-pixels SP3 and the third cathode electrode layer 163 may be electrically connected to each other at the undercut UC of the structure ST of each of the third sub-pixels SP3.

As such, according to an embodiment of the present disclosure, the organic light-emissive layer rendering the first color, the cathode electrode layer, and the passivation layer may be formed, and subsequently, the organic light rendering the second color may be additionally formed using the same process as that on the organic light-emissive layer rendering the first color and subsequently, the organic light rendering the third color may be additionally formed using the same process as that on the organic light-emissive layer rendering the first color.

Therefore, the passivation layer disposed on the organic light-emissive layer may act as a protective film that reduces deterioration of the organic light-emissive layer that may occur in a continuous process for forming the organic light-emissive layers corresponding to the sub-pixels. Thus, the damage to the organic light-emissive layer may be reduced.

A first planarization film 170a may be formed to cover the first sub-pixel SP1, the second sub-pixel SP2, and the third sub-pixel SP3.

The first planarization film 170a may be formed to cover the first passivation layer 171, the second passivation layer 172, and the third passivation layer 173.

In the present disclosure, the first planarization film 170a may be referred to as the first capping layer 170. The first planarization film 170a that has been subjected to an etching process as described later may be referred to as the first capping layer 170.

Referring to FIG. 6I and FIG. 7I, a partial area of each of the first capping layer 170, the first passivation layer 171, the second passivation layer 172, and the third passivation layer 173 may be etched such that an area of each of the first cathode electrode layer 161, the second cathode electrode layer 162, and the third cathode electrode layer 163 corresponding to each of the plurality of structures ST respectively positioned in the sub-pixels is exposed.

Specifically, the first planarization film 170a may be etched such that a thickness thereof is reduced by a predetermined thickness. The etching of the first planarization film 170a may be performed until a portion of the passivation layer corresponding to the structure ST is entirely removed such that a partial area of the cathode electrode layer is exposed to the outside.

As the portion of the passivation layer has been removed in this way, the cathode contact as a portion of the cathode electrode layer which is exposed to the outside may be formed.

Therefore, the first cathode contact 161c may be formed as a portion of the first cathode electrode layer 161. A second cathode contact 162c may be formed as a portion of the second cathode electrode layer 162, and a third cathode contact 163c may be formed as a portion of the third cathode electrode layer 163.

Referring to FIG. 6J and FIG. 7J, the power connection line 112 electrically connected to the exposed portion of each of the first cathode electrode layer 161, the second cathode electrode layer 162, and the third cathode electrode layer 163 may be formed on the first capping layer 170.

Accordingly, the power connection line 112 directly contacts the first cathode contact 161c of the first cathode electrode layer 161, directly contacts the second cathode contact 162c of the second cathode electrode layer 162 and directly contacts the third cathode contact 163c of the third cathode electrode layer 163. Thus, the voltage from the power line 20 can be applied to the cathode electrode layer via the power connection line 112.

Referring to FIG. 6K and FIG. 7K, the second capping layer 180 and the passivation layer 190 may be additionally formed to cover the first sub-pixel SP1, the second sub-pixel SP2, and the third sub-pixel SP3.

The display device and the method for manufacturing the display device according to an embodiment of the present disclosure as described above may be described as follows.

A first aspect of the present disclosure provides a display device comprising: a plurality of sub-pixels; a power line for applying a voltage to the plurality of sub-pixels; a plurality of structures respectively disposed in the plurality of sub-pixels; and a power connection line disposed on the plurality of structures so as to electrically connect the plurality of sub-pixels to the power line, wherein each of the sub-pixels includes an organic light-emissive layer, a cathode electrode layer, and a passivation layer stacked sequentially, wherein the organic light-emissive layers of the sub-pixels adjacent to each other are disconnected from each other, wherein the cathode electrode layers of the sub-pixels adjacent to each other are disconnected from each other, wherein the passivation layers of the sub-pixels adjacent to each other are disconnected from each other, wherein a cathode contact as a portion of the cathode electrode layer exposed through an opening defined in the passivation layer is disposed on the structure, wherein the power connection line is disposed to overlap the plurality of structures, wherein the power connection line contacts the cathode contact and thus is electrically connected to the cathode electrode layer.

In one implementation of the first aspect, the display device further comprises a plurality of data lines, each data line being disposed between the sub-pixels adjacent to each other, wherein each of the data lines is disposed so as not to overlap with the cathode electrode layer.

In one implementation of the first aspect, the plurality of sub-pixels are arranged in a matrix form along a first direction and a second direction intersecting the first direction, wherein the power connection line is formed in a grid pattern extending across the cathode contacts respectively disposed in the plurality of sub-pixels.

In one implementation of the first aspect, the power connection line is formed so as to cover an entire area of all of the plurality of sub-pixels, wherein the power connection line is made of a transparent material.

In one implementation of the first aspect, each of the sub-pixels includes an outermost boundary of the organic light-emissive layer, an outermost boundary of the cathode electrode layer, and an outermost boundary of the passivation layer, wherein the outermost boundary of the organic light-emissive layer is positioned inwardly of the outermost boundary of the passivation layer, wherein the outermost boundary of the cathode electrode layer is disposed between the outermost boundary of the organic light-emissive layer and the outermost boundary of the passivation layer.

In one implementation of the first aspect, the structure included in each of the sub-pixels is positioned inwardly of the outermost boundary of the organic light-emissive layer, the outermost boundary of the cathode electrode layer, and the outermost boundary of the passivation layer.

In one implementation of the first aspect, each of the sub-pixels includes a light-emitting area, wherein the structure is disposed in at least one side portion of the light-emitting area.

In one implementation of the first aspect, the power line is a low-potential voltage (VSS) line, wherein a low-potential voltage is applied to the cathode electrode layer included in each of the sub-pixels via the power connection line.

A second aspect of the present disclosure provides a display device comprising: a substrate having a plurality of sub-pixel areas defined thereon; a bank layer disposed on the substrate; a structure having a least a partial area disposed on the bank layer; an organic light-emissive layer, a cathode electrode layer, and a passivation layer sequentially stacked so as to cover the bank layer and the structure; and a power connection line disposed on the structure so as to overlap the structure, wherein a cathode contact as a portion of the cathode electrode layer exposed through an opening defined in the passivation layer is disposed on the structure, wherein the power connection line contacts the cathode contact and thus is electrically connected to the cathode electrode layer.

In one implementation of the second aspect, the organic light-emissive layers of the sub-pixels adjacent to each other are disconnected from each other, wherein the cathode electrode layers of the sub-pixels adjacent to each other are disconnected from each other, wherein the passivation layers of the sub-pixels adjacent to each other are disconnected from each other.

In one implementation of the second aspect, the display device further comprises a data line disposed on the substrate, wherein the data line is disposed so as not to overlap with the cathode electrode layer.

In one implementation of the second aspect, the display device further comprises: a data line disposed on the substrate; and a first capping layer disposed between the bank layer and the power connection line, wherein the bank layer and the first capping layer are disposed between the data line and the power connection line.

In one implementation of the second aspect, at least a partial area of the data line non-overlaps with the power connection line.

In one implementation of the second aspect, the first capping layer and the structure are disposed in the same layer based on the bank layer.

In one implementation of the second aspect, the display device further comprises a second capping layer disposed on the first capping layer so as to cover the power connection line.

In one implementation of the second aspect, the structure has a tapered shape.

In one implementation of the second aspect, the display device further comprises a power line as a low-potential voltage (VSS) line, wherein a low-potential voltage is applied to the cathode electrode layer included in each of the sub-pixels via the power connection line electrically connected to the power line.

A third aspect of the present disclosure provides a method for manufacturing a display device, the method comprising: forming a plurality of data lines on a substrate; forming a plurality of anode electrode layers so as to be respectively positioned in the plurality of sub-pixels; forming a bank layer including a plurality of openings respectively exposing portions of the plurality of anode electrode layers; forming a plurality of structures on the bank layer so as to be respectively positioned in the plurality of sub-pixels; forming a first protective layer and a first photoresist film so as to expose the opening corresponding to a first sub-pixel, sequentially forming a first organic light-emissive layer rendering a first color, a first cathode electrode layer, and a first passivation layer, and then removing the first protective layer and the first photoresist film; forming a second protective layer and a second photoresist film so as to expose the opening corresponding to a second sub-pixel, sequentially forming a second organic light-emissive layer rendering a second color, a second cathode electrode layer, and a second passivation layer, and then removing the second protective layer and the second photoresist film after; forming a third protective layer and a third photoresist film so as to expose the opening corresponding to a third sub-pixel, sequentially forming a third organic light-emissive layer rendering the third color, a third cathode electrode layer, and a third passivation layer, and then removing the third protective layer and the third photoresist film; forming a first capping layer so as to cover the first passivation layer, the second passivation layer, and the third passivation layer; etching a partial area of each of the first capping layer, the first passivation layer, the second passivation layer, and the third passivation layer such that a partial area of each of the first cathode electrode, the second cathode electrode, and the third cathode electrode overlapping the structure is exposed; and forming a power connection line on the first capping layer so as to be electrically connected to the exposed partial area of each of the first cathode electrode layer, the second cathode electrode layer, and the third cathode electrode layer.

In one implementation of the third aspect, forming the first capping layer includes forming the first capping layer such that the first capping layer and the structure are disposed in the same layer based on the bank layer.

In one implementation of the third aspect, the first organic light-emissive layer, the second organic light-emissive layer, and the third organic light-emissive layer are formed so as to be disconnected from each other, wherein the first cathode electrode layer, the second cathode electrode layer, and the third cathode electrode layer are formed so as to be disconnected from each other, wherein the first passivation layer, the second passivation layer, and the third passivation layer are formed so as to be disconnected from each other.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a plurality of sub-pixels;
a power line configured to supply a voltage;
a plurality of structures, each structure respectively disposed in a corresponding one of the plurality of sub-pixels; and
a power connection line overlapping the plurality of structures, the power connection line electrically connected to the plurality of sub-pixels and the power line, and supplies the voltage from the power line to the plurality of sub-pixels,
wherein each of the plurality of sub-pixels includes an organic light-emissive layer, a cathode electrode layer on the organic light-emissive layer, and a passivation layer on the cathode electrode layer, the passivation layer including an opening that exposes a portion of the cathode electrode layer that is on a corresponding structure from the plurality of structures such that the portion of the cathode electrode layer is in contact with the power connection line,
wherein organic light-emissive layers of adjacent sub-pixels from the plurality of sub-pixels are disconnected from each other, cathode electrode layers of the adjacent sub-pixels are disconnected from each other, and passivation layers of the adjacent sub-pixels are disconnected from each other.

2. The display device of claim 1, wherein the display device further comprises:
a plurality of data lines, each data line from the plurality of data lines disposed between a pair of adjacent sub-pixels adjacent from the plurality of sub-pixels and is non-overlapping with the cathode electrode layer of each of the pair of adjacent sub-pixels.

3. The display device of claim 1, wherein the plurality of sub-pixels are arranged in a matrix form along a first direction and a second direction that intersects the first direction, and the power connection line is formed in a grid pattern extending across the exposed portion of the cathode electrode layer in each of the plurality of sub-pixels.

4. The display device of claim 1, wherein the power connection line covers an entire area of all of the plurality of sub-pixels, the power connection line comprising a transparent material.

5. The display device of claim 1, wherein each of the plurality of sub-pixels includes an outermost boundary of the organic light-emissive layer, an outermost boundary of the cathode electrode layer, and an outermost boundary of the passivation layer,
wherein the outermost boundary of the organic light-emissive layer is inset from the outermost boundary of the passivation layer,
wherein the outermost boundary of the cathode electrode layer is between the outermost boundary of the organic light-emissive layer and the outermost boundary of the passivation layer.

6. The display device of claim 5, wherein the structure included in each of the plurality of sub-pixels is inset from the outermost boundary of the organic light-emissive layer, the outermost boundary of the cathode electrode layer, and the outermost boundary of the passivation layer.

7. The display device of claim 1, wherein each of the plurality of sub-pixels includes a light-emitting area, and the structure included in the sub-pixel is on at least one side of the light-emitting area without overlapping the at least one side of the light-emitting area.

8. The display device of claim 1, wherein the power line is a low-potential voltage line and the voltage is a low-potential voltage that is applied to the cathode electrode layer included in each of the plurality of sub-pixels via the power connection line.

9. A display device comprising:
a substrate;
a plurality of sub-pixels on the substrate;
a bank layer on the substrate;
a structure on the bank layer;
an organic light-emissive layer, a cathode electrode layer on the organic light-emissive layer, and a passivation layer on the cathode electrode layer in a sub-pixel from the plurality of sub-pixels such that a portion of the organic light-emissive layer, a portion of the cathode electrode layer, and a portion of the passivation layer overlap the bank layer and the structure, the passivation layer including an opening that exposes a portion of the cathode electrode layer that is on the structure; and
a power connection line overlapping the structure such that the structure is between the power connection line and the substrate,
wherein the portion of the cathode electrode layer is in contact with the power connection line.

10. The display device of claim 9, wherein organic light-emissive layers of adjacent sub-pixels from the plurality of sub-pixels are disconnected from each other, cathode electrode layers of the adjacent sub-pixels are disconnected from each other, and passivation layers of the adjacent sub-pixels are disconnected from each other.

11. The display device of claim 9, wherein the display device further comprises:
a data line on the substrate, the data line non-overlapping with the cathode electrode layer.

12. The display device of claim 9, wherein the display device further comprises:
a data line on substrate; and
a first capping layer between the bank layer and the power connection line,
wherein the bank layer and the first capping layer are between the data line and the power connection line.

13. The display device of claim 12, wherein at least a portion of the data line is non-overlapping with the power connection line.

14. The display device of claim 12, wherein the first capping layer and the structure are in a same layer on the bank layer.

15. The display device of claim 12, wherein the display device further comprises:
a second capping layer on the first capping layer, the second capping layer covering the power connection line.

16. The display device of claim 9, wherein the structure comprises a tapered shape.

17. The display device of claim 9, wherein the display device further comprises:
a power line configured to supply a low-potential voltage, the power line connected to the power connection line,
wherein the power connection line applies the low-potential voltage to the cathode electrode layer.

18. A display device comprising:
a substrate;
a bank on the substrate, the bank including an opening;
a structure on the bank that is non-overlapping with the opening;
a power connection line including a portion that overlaps the structure, the power connection line configured to supply a voltage;
an anode electrode layer in the opening;
an organic light-emissive layer including a first portion and a second portion, the first portion of the organic light-emissive layer on the anode electrode layer in the opening and the second portion of the organic light-emissive layer on the structure;
a cathode electrode layer including a first portion and a second portion, the first portion of the cathode electrode layer on the first portion of the organic light-emissive layer in the opening and the second portion of the cathode electrode layer on the second portion of the organic light-emissive layer and the structure, the second portion of the cathode electrode layer in contact with the portion of the power connection line that overlaps the structure and receives the voltage from the power connection line; and
a passivation layer including a first portion and a second portion, the first portion of the passivation layer on the first portion of the cathode electrode layer in the opening and the second portion of the passivation layer on the second portion of the organic light-emissive layer and the structure without being between the second portion of the cathode electrode layer and the portion of the power connection line that is in contact with the second portion of the cathode electrode layer.

19. The display device of claim 18, wherein the second portion of the passivation layer includes an end that is coplanar with an upper surface of the second portion of the cathode electrode layer that is in contact with the power connection line.

20. The display device of claim 18, wherein the display device further comprises:
a data line that is non-overlapping with the cathode electrode layer.

21. The display device of claim 19, further comprising:
a first capping layer on the bank, the first capping layer on a same layer as the structure; and
a second capping layer on the first capping layer and the power connection line.

22. The display device of claim 21, wherein an upper surface of the first capping layer is coplanar with the end of the second portion of the passivation layer and the upper surface of the second portion of the cathode electrode layer.

23. The display device of claim 18, further comprising:
a plurality of pixels are arranged in a matrix form along a first direction and a second direction that intersects the first direction,
wherein the power connection line comprises a grid pattern extending across the second portion of the cathode electrode layer.

24. The display device of claim 18, further comprising:
a plurality of pixels are arranged in a matrix form along a first direction and a second direction that intersects the first direction,
wherein the power connection line covers an entire area of all of the plurality of pixels and comprises a transparent material.
